(19) United States
(12) Patent Application Publication
(10) Pub. No.: US 2006/0011298 A1
(43) Pub. Date: Jan. 19, 2006

(54) Showerhead with branched gas receiving channel and apparatus including the same for use in manufacturing semiconductor substrates

(76) Inventors: Ji-Eun Lim, Seoul (KR); Byoung-Jae Bae, Gyeonggi-do (KR); Young-Bae Choi, Gyeonggi-do (KR)

Correspondence Address: Robert W. Glatz;Myers Bigel Sibley & Sajovec, Post Office Box 37428, Raleigh, NC, 27627, US

(21) Appl. No.: 11/177,890

(22) Filed: Jul. 8, 2005

(30) Foreign Application Priority Data
Jul. 15, 2004 (KR) 10-2004-55131

(51) Int. Cl. C23F 1/00; C23C 16/00

(52) U.S. Cl. 156/345.34; 118/715

(57) ABSTRACT

Showerheads for use in an apparatus for manufacturing a semiconductor substrate include an injection plate defining a bottom face of a gas receiving space in the showerhead and a gas receiving channel extending within the injection plate. A plurality of exhausting holes in the injection plate are coupled to the gas receiving channel. The exhausting holes are configured to exhaust gas from the gas receiving channel to the bottom face of the gas receiving space. A plurality of channels extend through the injection plate from the bottom face of the gas receiving space configured to flow gas from the bottom face of the gas receiving space out of the space.

### CROSS-REFERENCE TO RELATED APPLICATIONS

This patent application is related to and claims priority from Korean Patent Application 2004-55131, filed on Jul. 15, 2004, the contents of which are hereby incorporated by reference in their entirety.

### BACKGROUND OF THE INVENTION

The present invention relates to showerheads and apparatus for manufacturing integrated circuit devices, and more particularly, to apparatus for processing a semiconductor substrate.

Manufacturing of semiconductor (integrated circuit) devices generally involves a plurality of processes, such as deposition, photolithography, etching, and ion implantation. A chemical vapor deposition method typically used in manufacturing semiconductor devices operates by permeating a selected source gas into a reaction chamber, where the pressure and temperature of the reaction chamber are maintained uniformly to deposit a desired thin film on the surface of a semiconductor wafer positioned in the chamber.

A typical chemical vapor deposition apparatus has a chamber that may be well purged/vacated. The chamber generally has a supporting stand on which a wafer is placed and a shower head for supplying source gases onto the wafer. The shower head typically includes an internal space defined by injection plates. Receiving channels are generally formed in top wall of the shower head, through which gases are received into the space from external sources. Pluralities of holes for injecting the gases received in the space onto the wafer are typically formed in the shower head.

In a typical shower head, as the receiving channels through which gases are received are formed in the centers of the top walls, the gases are non-uniformly distributed in the space. As a result, a thin film that is deposited on the wafer may have a central portion that is thicker than at the edge. Such a non-uniformity problem may become more severe as the diameter of the wafer increases.

When a PZT thin film is deposited on the wafer, the gases used as source gases generally include a metal organic source gas having a large atomic weight. Such gases generally do not stay in the space of the shower head for a long time due to the weight thereof. As such, they may be, essentially, directly injected onto the wafer. Therefore, the source gases may not be uniformly distributed in the space of the shower head and deposition uniformity may deteriorate. In addition, a heater block for heating the source gases received in the shower head is sometimes provided around the shower head. It may be difficult to control the temperature of the source gases when the source gases only stay in the shower head for a short time.

Such deposition shower heads are also commonly made of stainless steel. Source gases for forming the PZT thin film may react to the stainless steel in the region close to the injection plate of the shower head. As a result, particles may be generated and introduced into the chamber.

### SUMMARY OF THE INVENTION

Embodiments of the present invention provide showerheads for use in an apparatus for manufacturing a semiconductor substrate. The showerheads include an injection plate defining a bottom face of a gas receiving space in the showerhead and a gas receiving channel extending within the injection plate. A plurality of exhausting holes in the injection plate are coupled to the gas receiving channel. The exhausting holes are configured to exhaust gas from the gas receiving channel to the bottom face of the gas receiving space. A plurality of channels extend through the injection plate from the bottom face of the gas receiving space configured to flow gas from the bottom face of the gas receiving space out of the space.

In other embodiments of the present invention, the showerhead is configured to be received in a chamber of the apparatus and a portion of the gas receiving channel is defined by an air gap defined by a side wall of the chamber and an outer wall of the injection plate positioned adjacent thereto. The gas receiving channel may be a branched channel including a plurality of respective division lines extending to respective ones of the plurality of exhausting holes. The division lines may be symmetrically arranged extending through the injection plate. A single receiving line configured to receive a gas into the gas receiving channel may be to the gas receiving channel and the division lines may be arranged with respect to the receiving line. A plurality of the division lines may include curved line portions extending in an arc circumferentially around the injection plate.

In further embodiments of the present invention, substrate treating apparatus for manufacturing a semiconductor substrate are provided including a showerhead as described above. The apparatus further includes a chamber and a supporting stand positioned in the chamber and configured to receiver a semiconductor wafer substrate thereon. The gas receiving channel may include a receiving line configured to receive a gas from outside the chamber, exhausting lines extending to the exhausting holes, and connection lines that branch from the receiving line and connect to the exhausting lines. The connection lines may include two connection lines and the connection lines may be symmetrically arranged with respect to the receiving line.

In other embodiments of the present invention, each of the connection lines includes a first division line divided from the receiving line and two second division lines divided from each of the first division lines. Each pair of the second division lines may be symmetrically arranged with respect to the associated one of the first division line. Each of the first division lines may include a curved line portion extending in an arc circumferentially around the injection plate and a straight line portion that extends from the curved line portion in an inward radial direction of the injection plate to define a straight line of a predetermined length. The curved line portion of each of the first division line may be an arc having a central angle of about 90° such that the straight line portions of each of the first division lines are arranged on a straight line. Each of the two second division lines divided from one of the first division lines may include a curved line portion that extends in an arc circumferentially around the injection plate and a straight line portion that extends from the curved line portion of the second division line in the radial direction of the injection plate in the inward radial direction to define a straight line of predetermined length, where the curved line portion of the second division line may be an arc having a central angle of about 45°. The curved line portion of the first division line may be an air gap formed between a side wall of the process chamber and an outer wall of the first injection plate.

In yet further embodiments of the present invention, the connection lines are arranged in the apparatus so that gas flows horizontally therein and the exhausting lines are arranged in the apparatus so that gas flows vertically therein. The connection lines connecting the receiving line to the exhausting lines may be arranged in a repeating pattern of dividing one line into two lines and of dividing each of the divided lines into two lines again a plurality of times between the receiving line and the exhausting lines. The connection lines may be configured to provide a substantially uniform pressure of gas injected from each of the plurality of exhausting holes.

In other embodiments of the present invention, the shower head further includes a second injection plate defining a bottom face of a second gas receiving space configured to receive a second gas. The second injection plate is positioned proximate the first injection plate and the second injection plate includes a second gas receiving channel configured to flow the second gas therein to the second space and a plurality of second channels extending through the second injection plate from the bottom face of the second gas receiving space configured to flow gas from the bottom face of the second gas receiving space out of the second gas receiving space. The first gas receiving space may be defined by a groove formed in a top surface of the first injection plate that defines a bottom face of the first gas receiving space, and the second gas receiving space may be formed by a groove formed in a top surface of the second injection plate that defines the bottom face of the second gas receiving space.

In further embodiments of the present invention, projections having a gas passage therein extend from the second injection plate to outlets of the plurality of channels extending through the first injection plate. The shower head may further include a first side wall arranged to surround the first injection plate and protrude above the first injection plate. A second side wall may be arranged to surround the second injection plate and protrude above the second injection plate and the projections may be insertion pipes. The second gas receiving channel may include a receiving line configured to connect to a gas supplying pipe, exhausting lines connected to a plurality of exhausting holes in the second injection plate that are configured to exhaust gas into the second gas receiving space and connection lines extending from the receiving line to the exhausting lines that are arranged in a repeating pattern of dividing one line into two lines and of dividing each of the divided lines into two lines again a plurality of times between the receiving line and the exhausting lines.

In yet other embodiments of the present invention, the substrate treating apparatus is a deposition apparatus. The first gas may be a material having larger atomic weight than an atomic weight of a material that comprises the second gas. The first gas may be a metal organic source gas. The first gas may be lead (Pb), zirconium (Zr), and/or titanimum (Ti), and the second gas may be oxygen. The second injection plate may be aluminum.

In further embodiments of the present invention, a substrate treating apparatus for performing a deposition process of forming a thin film on a substrate includes a chamber and a supporting stand arranged in the chamber such that a substrate is placed thereon. A shower head is arranged in the chamber to supply a gas onto the substrate placed on the supporting stand. The shower head includes injection plates arranged to form a plurality of layers such that spaces to which the gas is received are formed on the top surfaces of the injection plates. Each of the respective injection plates includes a gas receiving channel through which the gas is supplied to the space formed in the top surface thereof and holes that are channels through which the gas is exhausted from the space.

In yet other embodiments of the present invention, the gas receiving channel includes a receiving line connected to an outer supplying pipe and exhausting lines connected to the exhausting holes formed on the bottom of the second space. Connection lines are divided from the receiving line to be connected to the exhausting lines. The gas receiving line includes the two connection lines and the connection lines are symmetrical with each other based on the receiving line. The connection lines may be formed by repeating processes of dividing one line into two lines from the receiving line and of dividing each of the divided lines into two lines symmetrical with each other again at least once. The shower head may include a first injection plate arranged in the upper portion and a second injection plate arranged below the first injection plate. Protrusions inserted into the holes formed in the first injection plate and having holes inside are formed on the top surface of the second injection plate.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention. In the drawings:

FIG. 1 is a cross-sectional view illustrating a deposition apparatus according to some embodiments of the present invention;

FIG. 2 is an exploded perspective view illustrating a first injection plate and a first side wall according to some embodiments of the present invention;

FIG. 3 is a perspective view illustrating the first injection plate of FIG. 2 in a shower head according to some embodiments of the present invention;

FIG. 4 is an exploded perspective view illustrating a second injection plate and a second side wall according to some embodiments of the present invention;

FIG. 5 is a plan view of the first injection plate of FIG. 2;

FIG. 6 is a plan view of the second injection plate of FIG. 4;

FIG. 7 is a cross-sectional view illustrating source gas flow direction in the deposition apparatus of FIG. 1 according to some embodiments of the present invention;

FIG. 8 is a perspective view illustrating a first injection plate in a shower head according to further embodiments of the present invention;

FIG. 9 is a cross-sectional view illustrating a deposition apparatus including a shower head according to further embodiments of the present invention;

FIG. 10 is a perspective view of the first injection plate of FIG. 9 according to some embodiments of the present invention;

FIG. 11 is a perspective view of the second injection plate of FIG. 9 according to some embodiments of the present invention; and

FIG. 12 is a cross-sectional view illustrating a deposition apparatus according to other embodiments of the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Various embodiments of the present invention will now be described with reference to the figures. In some described embodiments, a shower head is used in an apparatus for performing a deposition process by way of example. However, in other embodiments, the shower head can be used in apparatus for performing various other semiconductor fabricating processes, such as an etching process. In addition, in some described embodiments, a metal organic chemical vapor deposition (MOCVD) apparatus is described by way of example. However, the shower head can be used with a variety of different types of chemical vapor deposition apparatuses in various embodiments of the present invention.

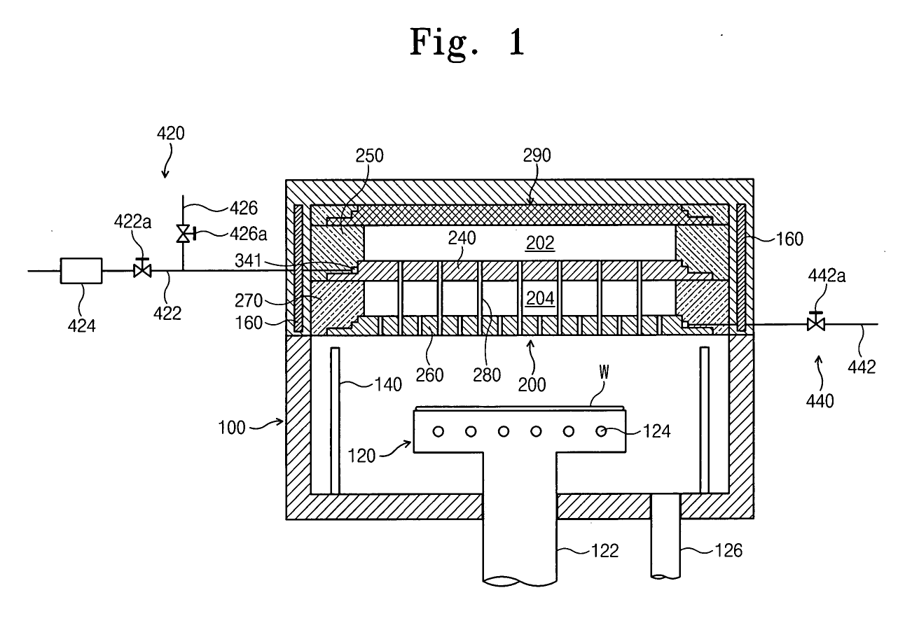

FIG. 1 is a sectional view of a metal organic chemical vapor deposition (MOCVD) apparatus according to some embodiments of the present invention. As shown in the embodiments of FIG. 1, the MOCVD apparatus includes a chamber 100 defining a space that may provide an environmentally controlled environment. An exhaust pipe 126 may be connected to an external pump. The exhaust pipe 126 is shown coupled through a wall of the chamber 100 so that the inside of the chamber 100 may be maintained at a desired pressure selected for a deposition process and so that reaction byproducts generated in the chamber 100 may be exhausted.

A supporting stand 120 is shown on which a semiconductor substrate, such as a wafer, may be placed. The supporting stand 120 is positioned at a bottom of the chamber 100 and supported by a support shaft 122. The supporting stand 120 may be disk shaped. A heater 124 is positioned in the supporting stand 120 to resolve source gases supplied to the upper portion of the heater 124 and to supply heat to the inside of the chamber 100 to facilitate smooth deposition of the source gases onto a wafer W. Thus, the heater 124 may be used to control heating of the wafer W to a temperature suitable to activate deposition of the source gas delivered material on the wafer W.

In the embodiments of FIG. 1, ring-shaped liners 140 are arranged between an inner surface of sidewalls of the chamber 100 and the supporting stand 120 so as to surround the supporting stand 120. The liners 140 may limit or prevent reacting of the inner surface of the sidewalls of the chamber 100 with the source gases and deposition of reaction byproducts on the inner surface of the walls of the chamber 100.

A shower head 200, configured to supply the source gases onto the wafer W on the supporting stand 120, is positioned in the upper portion of the chamber 100. The shower head 200 is shown facing the supporting stand 120. Heaters 160 may be positioned around the shower head 200 to heat the source gases received in the shower head 200 so that the source gases are maintained at a selected temperature suitable for a deposition process. The heaters 160 may also operate to control liquefying or resolving of the source gases while the source gases are still in the shower head 200, particularly when the source gases are metal organic precursor gases.

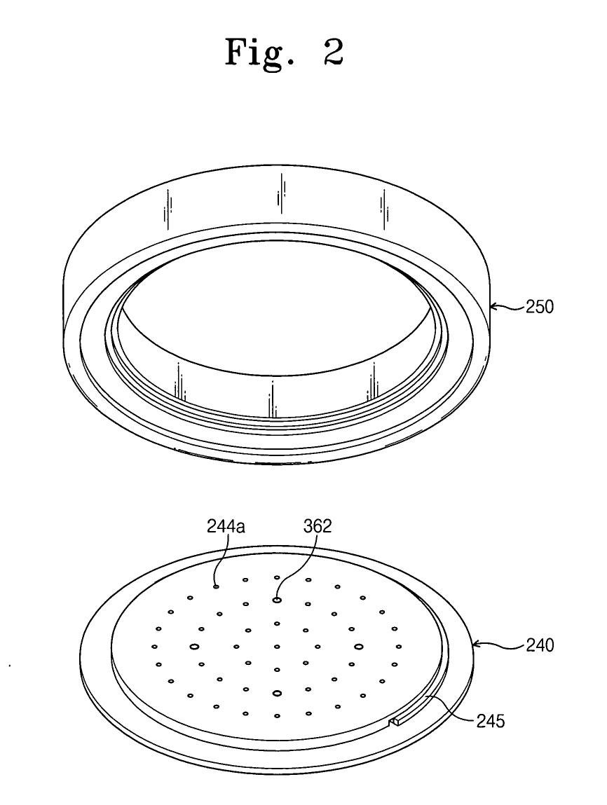

A source gas supplying portion configured to supply the source gases to the shower head 200 is arranged outside the chamber 100. The source gas supplying portion in the embodiments of FIG. 2 includes a first gas supplying portion 420 configured to supply a first source gas to the shower head 200 and a second gas supplying portion 440 configured to supply a second source gas to the shower head 200. For example, the first source gas may include a metal organic precursor gas that has a low vapor pressure and is liquid/solid at room temperature and is supplied in a vapor state. The second source gas may be gaseous at room temperature and may react with the first source gas. For example, when a PZT film is deposited on the wafer W, the first source gas may include lead (Pb), zirconium (Zr), and titanium (Ti) and the second source gas may include oxygen (O). The illustrated first gas supplying portion 420 includes a gas supplying pipe 422 provided with a vaporizer 424 that supplies the metal organic precursor gas to the shower head 200. A pipe 426 is coupled to the gas supplying pipe 422 at a selected location. The pipe 426 supplies a carrier gas that carries the vaporized metal organic precursor gas. An additional pipe (not shown) may also be coupled to the gas supplying pipe 422 to supply a fudge (e.g. purge/inert) gas. The second gas supplying portion 440 in the embodiments of FIG. 1 includes a gas supplying pipe 442 that supplies a gas including O to the shower head 200. Opening and closing valves 422a, 426a, and 442a for opening and closing inner channels are shown in the respective pipes. The valves 422a, 426a and 442a may also be configured to control an a flow rate or separate flow rate control valves may be provided in the respective pipes.

The shower head 200 of FIG. 1 has a cylindrical body that defines therein a first space 202 in which the first source gas is received and a second space 204 in which the second source gas is received. The first space 202 and the second space 204 are surrounded by a top wall 290, an injection plate 240 that defines a top wall of the second space 204 and a bottom wall of the first space 202, an injection plate 260 that defines a bottom wall of the second space 204 and respective side walls 250 and 270 and are partitioned by layers. The injection plate 240 operates as an injection plate of the first space 202 and, at the same time, may function as the top wall of the second space 204. The injection plate 240 separating the first and second space 202, 204 may be referred to herein as the first injection plate 240. The injection plate 260 may be referred to as the second injection plate 260. The top wall 290 of the first space 202 may be a separate part from the chamber 100 and the side wall 250 as illustrated in FIG. 1. However, the top wall of the chamber 100 may be used as the top wall of the first space 202 in other embodiments.

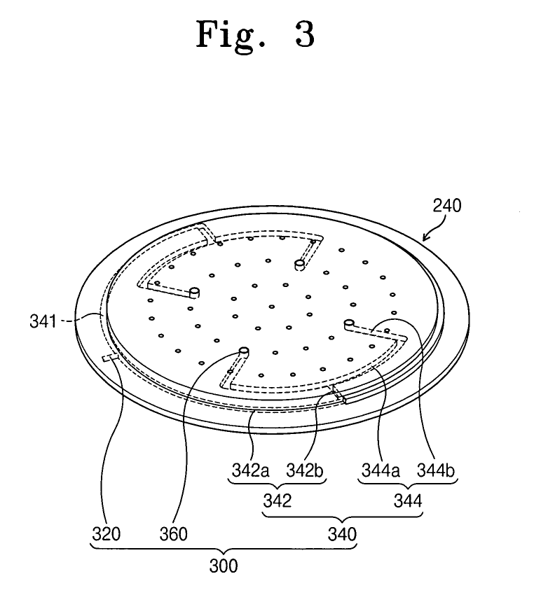

A metal organic source gas is generally much heavier than other gases used in semiconductor deposition processes. As a result, when the first source gas including the metal organic source gas is injected from the top to the bottom as shown in FIG. 1, the first source gas may not be well diffused through a wide region in the first space 202 but, instead, may be substantially directly injected from the shower head 200. As such, the first source gas may be non-uniformly deposited across different regions of the wafer W and it is difficult to control the temperature of the first source gas in the shower head 200. In some embodiments of the present invention, as illustrated in FIG. 3, the first source gas is injected from the bottom of the first space 202 to the first space 202 through a first gas receiving channel 300. As the first source gas is received to the first space 202 while being diffused like a jet flow in such embodiments, the first source gas may be more uniformly supplied to a wide region. It is also generally more difficult to control the temperature of the first source gas than the temperature of the second source gas. Therefore, the first space 202 may be arranged above the second space 204, such that the first source gas may stay in the shower head 200 for a longer time.

The first gas receiving channel 300 in the embodiments of FIG. 3 includes a receiving portion, a dividing portion, and an exhausting portion. The receiving portion receives the first source gas from outside the shower head 200 and has a receiving line connected to the gas supplying pipe 422. The exhausting portion exhausts the first source gas received in the shower head 200 to the first space 202 and has a plurality of exhausting lines in the illustrated embodiments of FIG. 3. The exhausting lines may be separated from each other at uniform intervals such that gases can be more uniformly received in the first space 202. The dividing portion is divided from the receiving line and has connection lines for connecting the receiving line and the exhausting lines to each other.

Each of the connection lines may have a plurality of division (branch) lines. For example, each of the connection lines may include a first division line divided from (branching off of) the receiving line and the exhausting lines may be connected to the first division lines. However, each of the connection lines may further include a plurality of second division (branch) lines divided from the first division lines and the exhausting lines may be connected to respective ones of the second division lines. In addition, each of the connection lines may further include a plurality of third division (branch) lines divided from the second division lines and the exhausting lines may be connected to respective ones of the third division lines. That is, each of the connection lines may include a first division line, second division lines, . . . , (k−1)'th division lines, . . . , nth division lines and one nth division line may be connected to one exhausting line. In some embodiments, the connection lines are formed so that the first source gas flows horizontally and that the exhausting lines are formed so that the first source gas flows vertically. However, the connection lines and/or the exhausting lines may be formed to provided inclined (angled) flow of the first source gas.

The first source gas in some embodiments is exhausted from the exhausting lines under the substantially same pressure so that the gas can be uniformly received into the first space 202. When three or more k'th division lines are divided from one (k−1)'th division line and/or the k'th division lines are not symmetrical with each other based on the (k−1)'th division line, the pressure of the gas that flows inside the k'th division lines may vary. As such, in some embodiments, the number of connection lines divided from the receiving line is two and the connection lines are symmetrical with each other relative to the receiving line. In some embodiments, two k'th division lines are divided from one (k−1)'th division line, the k'th division lines are divided so as to be symmetrical with each other relative to the (k−1)'the division line, and the exhausting lines are symmetrical with each other relative to the injection plate 240.

One receiving line or a plurality of receiving lines may be provided in various embodiments. However, in some embodiments, when a plurality of receiving lines are provided, a plurality of gas supplying pipes are also provided, which may result in more complicated equipment and the pressure and the temperature of the first source gas that flows through the gas supplying pipe 422 may be non-uniform. In other embodiments, only a single receiving line is provided in the shower head 200.

When the number of exhausting lines is too small, it may be difficult to uniformly supply the first source gas to the entire first space 202. When the number of exhausting lines is too large, the number of exhausting lines in the injection plate may increase to a point where it is difficult to manufacture the injection plate and division/branching of the lines becomes so many times that the gas may not flow smoothly. Therefore, in some embodiments, where up to nth division are lines formed in the injection plate, n may be selected dependent on the area of the injection plate (generally corresponding to the size of the wafer to be processed in the apparatus). In particular embodiments, where a deposition process is to be performed on the wafer of 300 mm, n is 2 and/or 3.

FIG. 2 is an exploded perspective view illustrating the first injection plate 240 and the first side wall 250 according to some embodiments of the present invention. FIG. 3 is a perspective view illustrating part of the first gas receiving channel 300 formed in the first injection plate 240 according to some embodiments of the present invention. The gas receiving and exhausting lines discussed generally above will now be described with reference to the particular illustrated embodiments of FIGS. 2 and 3. The illustrated gas receiving channel 300 includes a receiving line 320, connection lines 340, and four exhausting lines 360. The receiving line 320 is illustrated as a horizontal straight line and is divided into two connection lines 340. Note that, in FIG. 3, numbering is only shown with reference to a first one of the connection lines 340, with the second portion of the distribution network (on the top as seen in FIG. 3) shown as being symmetrical to the numbered portion. The receiving line 320 may be formed by a hole extending through a side wall of the chamber 100 and the first side wall 250 of the shower head. The exhausting lines 360 are connected to exhausting holes 362 (FIG. 2) formed on a face of the injection plate 240 defining the bottom of the first space 202.

As noted above, the two connection lines 340 are illustrated as formed to be symmetrical with each other about a line defined by the receiving line 320. The connection lines 340 are shown as defining two first division lines 342 divided from the receiving line 320 and two second division lines 344 divided from the first division lines 342. Each of the first division lines 342 includes a curved portion 342a that is an arc and a straight line portion 342b that extends from the curved line portion 342a toward the inside in the radial direction of the injection plate 240 to form a straight line of predetermined length. The curved line portion 342a of each of the first division lines 342 may be an arc having a central angle of about 90° so that the straight line portions 342b of the two first division lines 342 divided from the receiving line 320 are arranged along the same straight line, which may pass through a midpoint of the injection plate 240. The illustrated two second division lines 344 branching from each straight line portion 342b are divided from the first division lines 342, respectively, so as to be symmetrical with each other. Each of the second division lines 344 is illustrated as including a curved line portion 344a that is an arc and a straight line portion 344b that extends from the curved line portion 344a toward the inside in the radial direction of the injection plate 240 to form a straight line of predetermined length. The curved line portion 344a of each of the second division lines 344 may be an arc having a central angle of about 45°. The exhausting lines 360 in the illustrated embodiments connect to the first space 202 from the ends of the second division lines 344. In some embodiments, the connection lines 340 are formed on a horizontal plane and the exhausting lines 360 are perpendicular to the connection lines 340.

As seen in FIGS. 1 and 2, the first side wall 250 is arranged to surround the first injection plate 240 and extend above the top end of the first injection plate 240. The first side wall 250 in the illustrated embodiments can be attached to and detached from the first injection plate 240 and may be coupled to the first injection plate 240 by conventional connection means, such as screws. The first side wall 250 associated with the first injection plate 240 may be formed so that an air gap 341 (FIGS. 1 and 3) is formed between the first injection plate 240 and the first side wall 250 when the first injection plate 240 and the first side wall 250 are positioned in adjacent relationship to each other. The air gap 341 may be used as one of the above described division lines for receiving gas. FIG. 3 illustrates some embodiments of the structure of the injection plate 240 to form the air gap 341.

Referring again to the embodiments of FIG. 2, the inside of the first side wall 250 is formed to have a plurality of steps and the side surface of the first injection plate 240 has a plurality of steps formed to be engaged with the steps formed in the first side wall 250. An intermediate step 245 of the first injection plate 240 is shown as being formed only over half of the circumference of the first injection plate 240. Therefore, when the first injection plate 240 and the first side wall 250 are combined with each other, the air gap 341 of FIG. 3 may be formed between the first injection plate 240 and the first side wall 250 (where the step 245 would otherwise extend). The receiving line 320 may be formed in the first side wall 250, the air gap 341 may be provided as the curved portions 342a of the first division lines 342, and the straight line portions 342b of the first division lines, the second division lines 344, and the exhausting lines 360 may be formed as holes in the first injection plate 240.

In some embodiments, the arrangement, the length, and the structure of the first division lines 342 and the second division lines 344 and the arrangement of the exhausting lines 360 may operate to maintain the first source gas at substantially the same pressure in the exhausting lines 360. However, the arrangement, the length, and the structure of the first division lines 342 and the second division lines 344 and the arrangement of the exhausting lines 360 may take various other forms in further embodiments of the present invention.

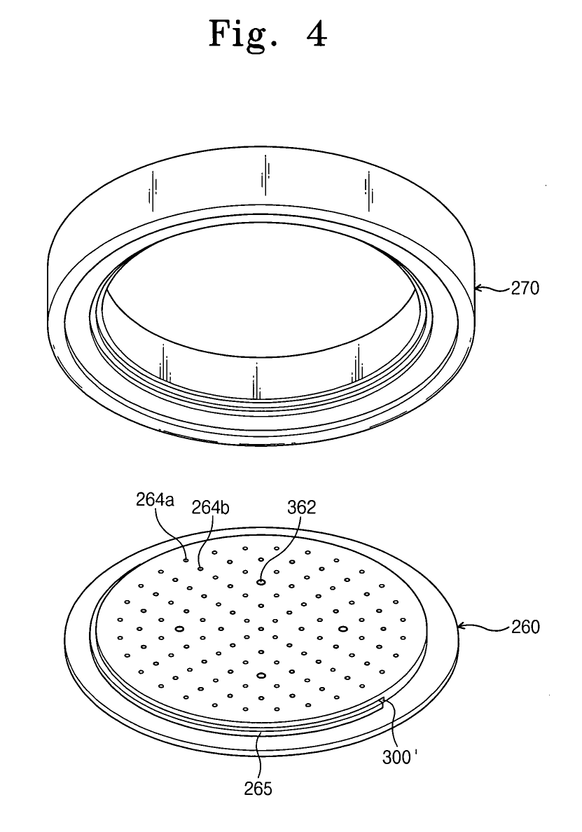

In some embodiments of the present invention, the shower head is arranged so the second source gas be substantially uniformly injected downward into the shower head 200. As seen in the embodiments of FIG. 4, a gas receiving channel 300′, which is a channel through which gases are transmitted to the second space 204, is formed in the second injection plate 260. FIG. 4 is an exploded perspective view illustrating the second injection plate 260 and the second side wall 270. Because the gas receiving channel 300′ formed in the second injection plate 260 for the embodiments illustrated in FIG. 4 has substantially the same structure as the gas receiving channel 300 formed in the first injection plate 240, detailed description thereof will be omitted herein. The gas receiving channel 300′ formed in the second injection plate 260 may be arranged on the opposite side of the gas receiving channel 300 formed in the first injection plate 240, such that the arrangement of the gas supplying pipes 422 and 442 of FIG. 1 may be simplified by providing separation therebetween. For example, if the gas receiving channel 300 is formed on the right side of the first injection plate 240, the gas receiving channel 300′ may be formed on the left side of the second injection plate 260. The gas receiving channel 300′ formed in the second injection plate 260 may further be arranged so as to face the gas receiving channel 300 formed in the first injection plate 240.

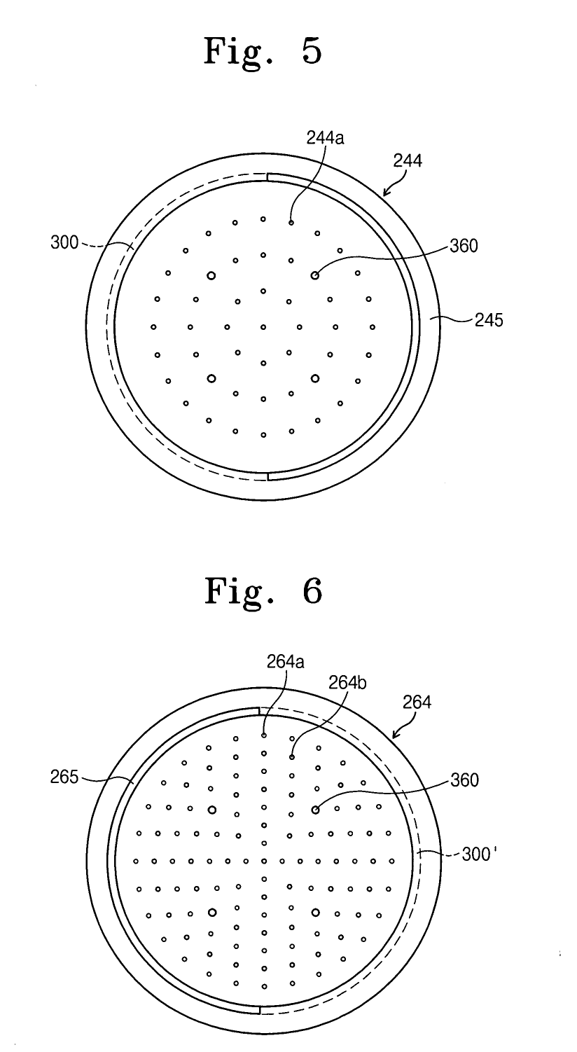

FIGS. 5 and 6 are plan views of the first injection plate 240 and the second injection plate 260, respectively, according to some embodiments of the present invention. As seen in the embodiments of FIGS. 5 and 6, a plurality of first holes 244a are formed in the first injection plate 240 and a plurality of second holes 264a and a plurality of third holes 264b are formed in the first injection plate 240. The third holes 264b are formed so as to face the first holes 244a in an up and down direction and the first holes 244a and the third holes 264b that face each other are connected to each other by an insertion pipe 280 (FIG. 1). The first holes 244a may be arranged at uniform intervals throughout the first injection plate 240 and the second holes 264a may be formed between the third holes 264b arranged at uniform intervals over the first injection plate 240.

In some embodiments, the first injection plate 250 and the second injection plate 260 are made of a material that is substantially non-reactive with the source gases and the first side wall is made of a material that is substantially not transformed thereby. For example, the first injection plate 240 and the second injection plate 260 may be made of aluminum and the first side wall and the second side wall may be made of stainless steel. In particular embodiments, where a gas including Pb, Zr, and Ti and a gas including O are intended to coexist in the region under the shower head 200, the inner plate 264 of the second injection plate 260 may be made of aluminum, which is generally not reactive with to these gases.

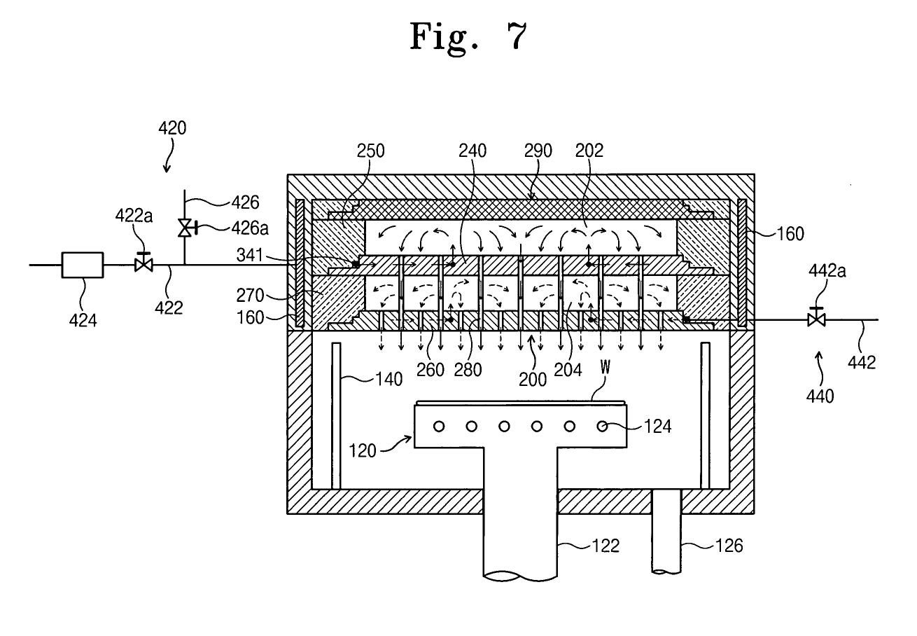

FIG. 7 illustrates the direction in which the source gases flow in the apparatus of FIG. 1 according to some embodiments of the present invention. As seen in the embodiments of FIG. 7, the first source gas is exhausted to the first space 202 through the first gas receiving channel 300 formed in the first injection plate 240 and is substantially uniformly diffused into the first space 202. The first source gas is then injected downward from the first space 202 in the shower head 200 through the insertion pipe 280. The second source gas is exhausted to the second space 204 through the second gas receiving channel 300′ formed in the second injection plate 260 and is substantially uniformly diffused into the second space 204. The second source gas is then injected downward from the second space 204 in the shower head 200 through the second holes 264a. As a result, when a deposition process is performed using a chemical vapor deposition method, the first source gas and the second source gas may be simultaneously supplied to a wafer W during the deposition process. When the deposition process is performed using an atomic layer deposition method, the first source gas and the second source gas may be sequentially supplied to the wafer W.

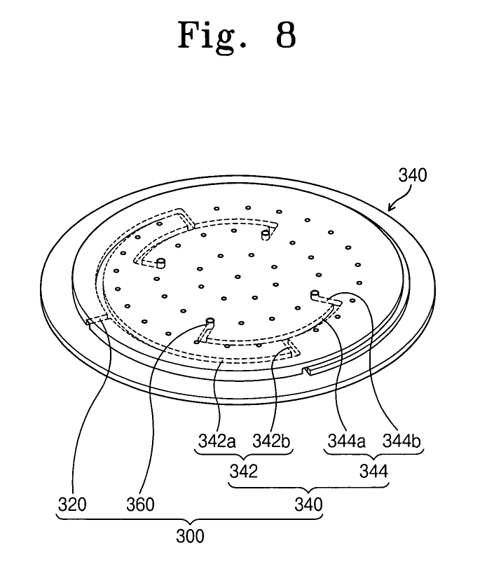

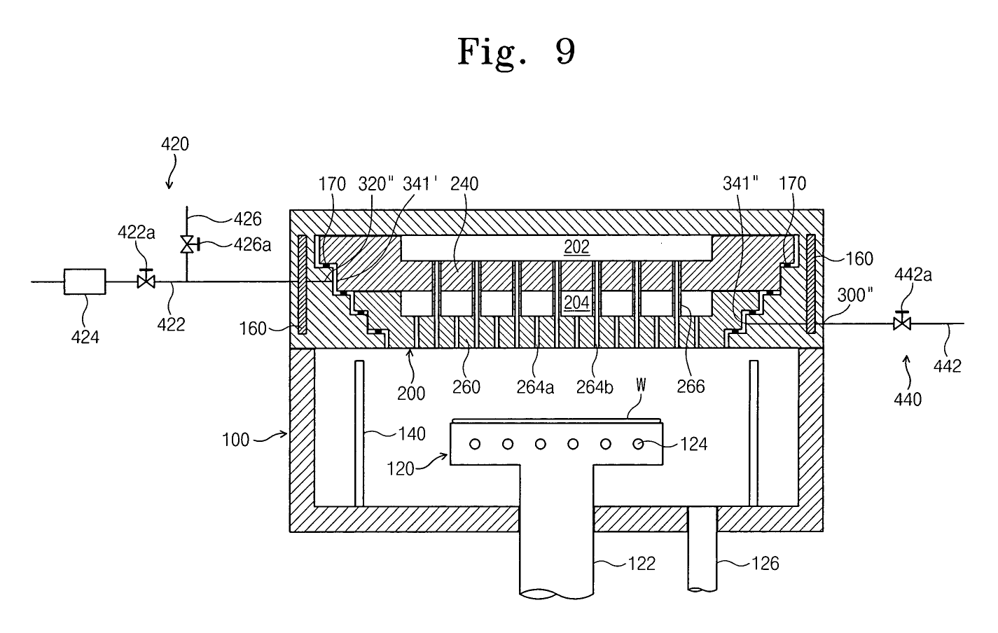

For some embodiments of the present invention using two kinds of source gas in the deposition process, both of the spaces 202 and 204 are formed in the shower head 200. When three or more source gases are used for the process, three or more spaces may be formed in the shower bead 200. Furthermore, when the process is performed using the atomic layer deposition method, a shower head 200 having the above-described multi-space structure may be used or a single space may be formed in the shower head 200 and the first source gas, the fudge gas (i.e., purging gas), and the second source gas may be sequentially supplied to the space. In such embodiments, the first division line 342a may be defined by a space between the first side wall 242 of the injection plate and the first injection plate 240. Alternatively, as illustrated in FIG. 8, the first division lines 342a may be formed in the first injection plate 240, like the other division lines, as holes.

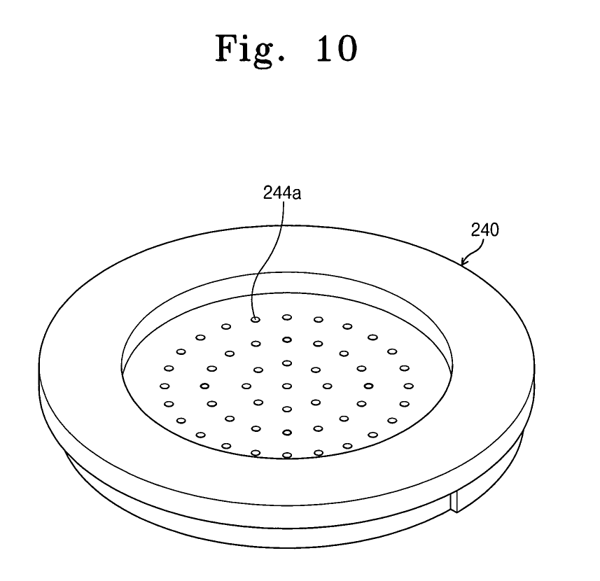

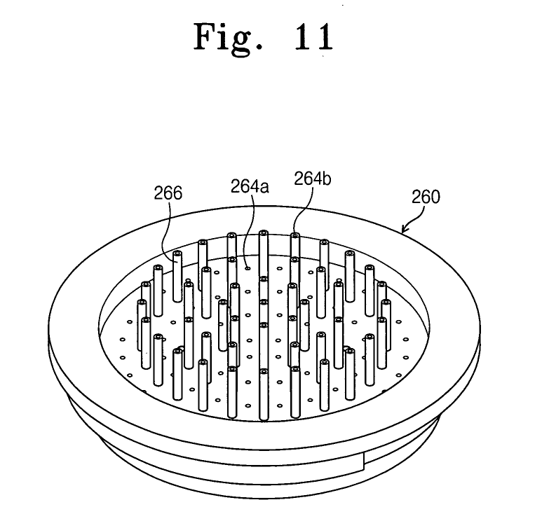

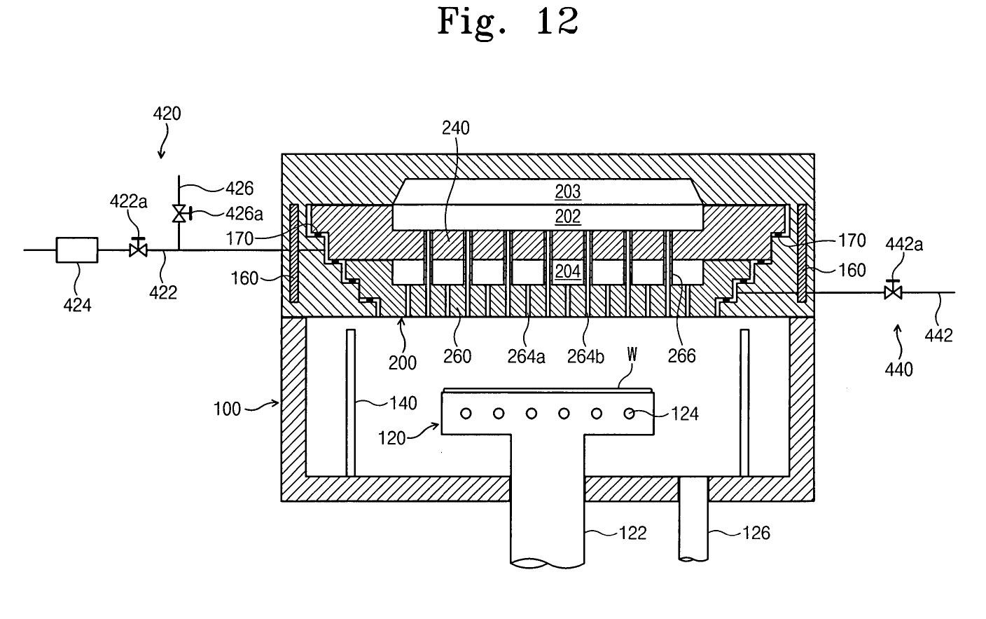

FIG. 9 is a cross-sectional view illustrating a deposition apparatus including the shower head 200 according to further embodiments of the present invention. FIG. 10 is a perspective view illustrating the first injection plate 240 according to some embodiments of the present invention. FIG. 11 is a perspective view illustrating the second injection plate 260 according to some embodiments of the present invention. In the apparatus of the embodiments of FIG. 9, various of the features, excluding the structure of the shower head 200, are substantially the same as the corresponding features illustrated in FIG. 1 and detailed description thereof will be omitted. Also, as the shape, the structure, and the arrangement of the second gas receiving channel 300′ are substantially the same as the shape, the structure, and the arrangement of the first gas receiving channel 300, detailed description thereof will be omitted. The apparatus illustrated in FIG. 9 will now be described primarily with reference to differences between the apparatus illustrated in FIG. 9 and the apparatus illustrated in FIG. 1.

Referring to the embodiments of FIGS. 9 to 11, the shower head 200 includes the first injection plate 240 and the second injection plate 260. The first injection plate 240 and the second injection plate 260 are arranged to be laminated in an up and down direction (as shown in the figures). A groove for providing the first space 202 is formed in the top surface of the first injection plate 240. A groove for providing the second space 204 is formed in the top surface of the second injection plate 260. In the inside wall of the chamber 100, the portion with which the shower head 200 will contact is formed to have steps. The shower head 200 of the embodiments of FIGS. 9-11 does not include the first side wall 250 and the second side wall 270 of the embodiments of FIG. 1. The first injection plate 240 and the second injection plate 260 may be directly combined with the chamber 100.

The receiving line 320″ of the first gas receiving channel 300 and the second gas receiving channel 300″ are illustrated formed on the side wall of the chamber 100. The curved line portions 344a of the respective first and second gas first division lines 344 (see FIG. 3) are formed by air gap 341′ formed between the first injection plate 240 and the side wall of the chamber 100 and by air gap 341″ formed between the second injection plate 260 and the side wall of the chamber 100, respectively. O-rings 170 are shown provided up and down the air gaps, which may limit or even prevent the gases received in the air gaps 341′, 341″ from being exhausted to the outside.

For some embodiments, the first holes 244a (FIG. 10) are formed in the first injection plate 240 and the second holes 264a and the third holes 264b (FIG. 11) are formed in the second injection plate 260. Protrusions 266, inserted into the first holes 244a, are formed on the top surface of the second injection plate 260 and the above-described third holes 264b are aligned with the protrusions 266. The first source gas received in the first space 202 is injected downwardly through the protrusions 266 and the third holes 264b. The second source gas received in the second space 204 is injected downwardly through the second holes 264a.

The second injection plate 260 may be made of aluminum, which may not react to the first source gas and/or the second source gas. The first injection plate 240 may be made of aluminum and/or stainless steel.

FIG. 12 illustrates a modification of the apparatus of FIG. 9 according to further embodiments of the present invention. The first space 202 and the second space 204 in these illustrated embodiments may have enough height so that the gases received to the first space 202 and the second space 204 can be substantially uniformly diffused into the respective spaces. In particular, the first space 202, where a metal organic precursor gas may be received as first source gas, may have a height selected to accommodate and distribute such a source gas. To provide a greater height, the embodiments of FIG. 12 include a groove formed in the top surface of the chamber 100 that provides in combination with the first injection plate 240, a first space 202 with an increased height as compared to the embodiments of FIG. 9.

With some embodiments of the present invention, as gases may be more uniformly injected from a shower head onto a wafer as compared with a conventional apparatus, a thin film may be more uniformly deposited on the entire target region of the wafer. In some embodiments, where a metal organic source gas may stay in the shower head for a long time, it may be possible to readily control the temperature of the source gases. The lowermost injection plate among the injection plates of the shower head may be made of aluminum in some embodiments, which may limit or prevent the injection plate from reacting to the source gases in the deposition chamber.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A showerhead for use in an apparatus for manufacturing a semiconductor substrate, the showerhead comprising:
an injection plate defining a bottom face of a gas receiving space in the showerhead;
a gas receiving channel extending within the injection plate;
a plurality of exhausting holes in the injection plate coupled to the gas receiving channel, the exhausting holes being configured to exhaust gas from the gas receiving channel to the bottom face of the gas receiving space; and
a plurality of channels extending through the injection plate from the bottom face of the gas receiving space configured to flow gas from the bottom face of the gas receiving space out of the space.

2. The showerhead of claim 1, wherein the showerhead is configured to be received in a chamber of the apparatus and wherein a portion of the gas receiving channel is defined by an air gap defined by a side wall of the chamber and an outer wall of the injection plate positioned adjacent thereto.

3. The showerhead of claim 1 wherein the gas receiving channel comprises a branched channel including a plurality of respective division lines extending to respective ones of the plurality of exhausting holes.

4. The showerhead of claim 3 wherein the division lines are symmetrically arranged extending through the injection plate.

5. The showerhead of claim 4 wherein a single receiving line configured to receive a gas into the gas receiving channel is coupled to the gas receiving channel and wherein the division lines are symmetrically arranged with respect to the receiving line.

6. The showerhead of claim 3 wherein a plurality of the division lines comprise curved line portions extending in an arc circumferentially around the injection plate.

7. A substrate treating apparatus for manufacturing a semiconductor substrate including the showerhead of claim 1, the apparatus further comprising:
a chamber; and
a supporting stand positioned in the chamber and configured to receiver a semiconductor wafer substrate thereon.

8. The substrate treating apparatus of claim 7, wherein the gas receiving channel comprises:
a receiving line configured to receive a gas from outside the chamber;
exhausting lines extending to the exhausting holes; and
connection lines that branch from the receiving line and connect to the exhausting lines.

9. The substrate treating apparatus of claim 8, wherein the connection lines comprise two connection lines and wherein the connection lines are symmetrically arranged with respect to the receiving line.

10. The substrate treating apparatus of claim 9, wherein each of the connection lines comprises:
a first division line divided from the receiving line; and
two second division lines divided from each of the first division lines, wherein each pair of the second division lines are symmetrically arranged with respect to the associated one of the first division line.

11. The substrate treating apparatus of claim 10, wherein each of the first division lines comprises:
a curved line portion extending in an arc circumferentially around the injection plate; and
a straight line portion that extends from the curved line portion in an inward radial direction of the injection plate to define a straight line of a predetermined length;
wherein the curved line portion of each of the first division line is an arc having a central angle of about 90° such that the straight line portions of each of the first division lines are arranged on a straight line.

12. The substrate treating apparatus of claim 11, wherein each of the two second division lines divided from one of the first division lines comprises:
a curved line portion that extends in an arc circumferentially around the injection plate; and
a straight line portion that extends from the curved line portion of the second division line in the radial direction of the injection plate in the inward radial direction to define a straight line of predetermined length;
wherein the curved line portion of the second division line is an arc having a central angle of about 45°.

13. The substrate treating apparatus of claim 10, wherein the curved line portion of the first division line comprises an air gap formed between a side wall of the process chamber and an outer wall of the first injection plate.

14. The substrate treating apparatus of claim 8, wherein the connection lines are arranged in the apparatus so that gas flows horizontally therein and wherein the exhausting lines are arranged in the apparatus so that gas flows vertically therein.

15. The substrate treating apparatus of claim 8, wherein the connection lines connecting the receiving line to the exhausting lines are arranged in a repeating pattern of dividing one line into two lines and of dividing each of the divided lines into two lines again a plurality of times between the receiving line and the exhausting lines.

16. The substrate treating apparatus of claim 15, wherein the connection lines are configured to provide a substantially uniform pressure of gas injected from each of the plurality of exhausting holes.

17. The showerhead of claim 1, wherein the shower head further comprises:
a second injection plate defining a bottom face of a second gas receiving space configured to receive a second gas, the second injection plate being positioned proximate the first injection plate, and
wherein the second injection plate includes a second gas receiving channel configured to flow the second gas therein to the second space and a plurality of second channels extending through the second injection plate from the bottom face of the second gas receiving space configured to flow gas from the bottom face of the second gas receiving space out of the second gas receiving space.

18. The showerhead of claim 17, wherein the first gas receiving space is defined by a groove formed in a top surface of the first injection plate that defines a bottom face of the first gas receiving space, and wherein the second gas receiving space is formed by a groove formed in a top surface of the second injection plate that defines the bottom face of the second gas receiving space.

19. The showerhead of claim 17, further comprising projections having a gas passage therein extending from the second injection plate to outlets of the plurality of channels extending through the first injection plate.

20. The showerhead of claim 19, wherein the shower head further comprises:
a first side wall arranged to surround the first injection plate and protrude above the first injection plate;
a second side wall arranged to surround the second injection plate and protrude above the second injection plate; and
wherein the projections comprise insertion pipes.

21. The showerhead of claim 17, wherein the second gas receiving channel comprises:
a receiving line configured to connect to a gas supplying pipe;
exhausting lines connected to a plurality of exhausting holes in the second injection plate that are configured to exhaust gas into the second gas receiving space; and
connection lines extending from the receiving line to the exhausting lines that are arranged in a repeating pattern of dividing one line into two lines and of dividing each of the divided lines into two lines again a plurality of times between the receiving line and the exhausting lines.

22. The showerhead of claim 17, wherein the apparatus is a deposition apparatus.

23. The showerhead of claim 22, wherein the first gas comprises a material having larger atomic weight than an atomic weight of a material that comprises the second gas.

24. The showerhead of claim 22, wherein the first gas is a metal organic source gas.

25. The showerhead of claim 24, wherein the first gas comprises lead (Pb), zirconium (Zr), and/or titanimum (Ti), and wherein the second gas comprises oxygen.

26. The showerhead of claim 25, wherein the second injection plate comprises aluminum.

27. A substrate treating apparatus for performing a deposition process of forming a thin film on a substrate, the substrate treating apparatus comprising:
a chamber;
a supporting stand arranged in the chamber such that a substrate is placed thereon; and
a shower head arranged in the chamber to supply a gas onto the substrate placed on the supporting stand,
wherein the shower head comprises injection plates arranged to form a plurality of layers such that spaces to which the gas is received are formed on the top surfaces of the injection plates, and
wherein each of the respective injection plates comprises a gas receiving channel through which the gas is supplied to the space formed in the top surface thereof and holes that are channels through which the gas is exhausted from the space.

28. The substrate treating apparatus of claim 27, wherein the gas receiving channel comprises:
a receiving line connected to an outer supplying pipe;
exhausting lines connected to the exhausting holes formed on the bottom of the second space; and
connection lines divided from the receiving line to be connected to the exhausting lines,
wherein the gas receiving line comprises the two connection lines, and
wherein the connection lines are symmetrical with each other based on the receiving line.

29. The substrate treating apparatus of claim 28, wherein the connection lines are formed by repeating processes of dividing one line into two lines from the receiving line and of dividing each of the divided lines into two lines symmetrical with each other again at least once.

30. The substrate treating apparatus of claim 27, wherein the shower head comprises:
a first injection plate arranged in the upper portion; and
a second injection plate arranged below the first injection plate,
wherein protrusions inserted into the holes formed in the first injection plate and having holes inside are formed on the top surface of the second injection plate.
